(19) United States
(12) Patent Application Publication
(10) Pub. No.: US 2026/0029712 A1
(43) Pub. Date: Jan. 29, 2026

(54) COMPOSITION FOR FORMING THIN FILM AND METHOD OF MANUFACTURING SEMICONDUCTOR ELEMENT

(71) Applicant: Daicel Corporation, Osaka-shi, Osaka (JP)

(72) Inventors: Kenji MOCHIDA, Tokyo (JP); Tsubasa MIKI, Tokyo (JP)

(73) Assignee: Daicel Corporation, Osaka-shi, Osaka (JP)

(21) Appl. No.: 18/995,069

(22) PCT Filed: Aug. 21, 2023
(86) PCT No.: PCT/JP2023/030041

§ 371 Date: Jan. 15, 2025

(30) Foreign Application Priority Data
Aug. 24, 2022 (JP) 2022-132950

(51) Int. Cl. G03F 7/021; G03F 7/004; G03F 7/11; H01L 21/027; H01L 21/311

(52) U.S. Cl. CPC G03F 7/0215; G03F 7/0048; G03F 7/11; H01L 21/0271; H01L 21/31111; H01L 21/31144

(57) ABSTRACT

Provided is a composition containing a solvent (I); and a cellulose derivative having a constituent unit or a salt thereof (II).

### TECHNICAL FIELD

The present disclosure relates to a composition for forming a thin film and a method of manufacturing a semiconductor element using the composition for forming a thin film. The present disclosure claims priority from JP 2022-132950 filed in Japan on Aug. 24, 2022, the contents of which are incorporated herein by reference.

### BACKGROUND ART

In the manufacture of semiconductor elements, resin films are used in resist films used in photolithography, diaphragms, photosensitive layers, light-emitting layers, insulating layers, and the like.

For example, Patent Document 1 describes a resist composition formed by dissolving a resin in which one or some of hydroxyl groups of a polyhydroxystyrene-based resin as a polymer compound are protected with an acid-dissociable dissolution-inhibiting group in an organic solvent containing propylene glycol monomethyl ether. The document also describes that spin coating with the composition can uniformly form a thick film containing the resin.

### CITATION LIST

### Patent Document

Patent Document 1: JP 2007-248727 A

### SUMMARY OF INVENTION

### Technical Problem

However, it has not been known in the art that a coating film containing water-soluble cellulose as a polymer compound can be formed by a spin-coating method.

In addition, when the present inventors tried to implement this method, the spin-coating method easily caused radial non-uniformity in the film thickness because the water-soluble cellulose dissolved in water had a high viscosity, making it difficult to form a uniform coating film. Furthermore, the viscosity can be reduced by diluting the water-dissolved material of the water-soluble cellulose with water. However, because of the high surface tension of water, it was still difficult to form a uniform coating film by a spin-coating method.

Thus, an object of the present disclosure is to provide a composition capable of uniformly forming a thin film containing water-soluble cellulose by a spin-coating method.

Another object of the present disclosure is to provide a method of manufacturing a semiconductor element using the composition.

### Solution to Problem

As a result of diligent studies to solve the above problems, the present inventors have found that a composition obtained by dissolving a cellulose derivative having a constituent unit represented by Formula (c) below or a salt thereof in a solvent with an SP value of 9.8 (cal/cm³)^{1/2} or more has excellent coating properties and can form a uniform thin film by a spin-coating method. The present disclosure has been completed based on these findings.

That is, the present disclosure provides a composition for forming a thin film, the composition containing:
a solvent (I) with an SP value of 9.8 (cal/cm³)^{1/2} or more at 25° C., the value calculated by Fedors' method; and
a cellulose derivative having a constituent unit represented by Formula (c) below or a salt thereof (II) (which may be referred to as “the cellulose derivative (II)” in the present specification):

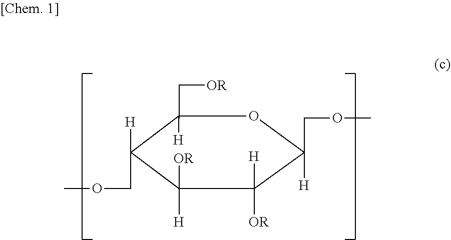

where three Rs are identical or different and represent a hydrogen atom, a hydrocarbon group, or a group in which two or more hydrocarbon groups are bonded through a linking group, and the hydrocarbon group may have a hydroxyl group or a carboxyl group, with proviso that at least one of the three Rs is a hydrocarbon group or a group in which two or more hydrocarbon groups are bonded through a linking group.

The present disclosure also provides the composition for forming a thin film, in which the solvent (I) is a solvent represented by Formula (1) below:

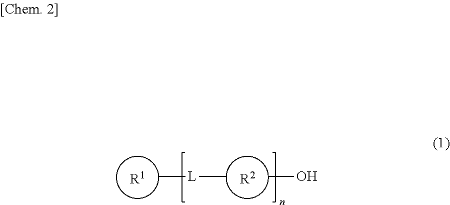

where L represents a single bond, an ether bond, or an ester bond, R¹ represents an alkyl group or a phenyl group, R² represents an alkylene group, R¹ and R² may be bonded to each other to form a ring together with L, a total number of carbon atoms of R¹ and R² is from 3 to 10, and n represents an integer of 1 or more.

The present disclosure also provides the composition for forming a thin film, in which the solvent (I) contains propylene glycol monomethyl ether.

The present disclosure also provides the composition for forming a thin film, in which a content of water is 10 wt. % or less of a total amount of the composition.

The present disclosure also provides the composition for forming a thin film, in which a content of the cellulose derivative or a salt thereof (II) in the composition is 30 wt. % or more of a total amount of a non-volatile component contained in the composition.

The present disclosure also provides a method of manufacturing a semiconductor element using the composition for forming a thin film.

The present disclosure also provides a method of manufacturing a semiconductor element, the method obtaining a semiconductor element through (1) and (2) below:
(1) applying the composition for forming a thin film to a surface layer of silicon, the surface layer including an oxide film and a nitride film, to form a thin film containing the cellulose derivative or a salt thereof (II) to obtain a [thin film/surface layer/silicon] laminate; and
(2) bringing an acidic etching liquid selectively etching one of the oxide film or the nitride film into contact with the [thin film/surface layer/silicon] laminate to selectively etch one of the oxide film or the nitride film included in the surface layer.

The present disclosure also provides the method of manufacturing a semiconductor element, in which the acidic etching liquid is at least one selected from hydrofluoric acid, ammonium fluoride, and a mixture of these.

### Advantageous Effects of Invention

The composition of the present disclosure has excellent coating properties and can form a thin film with a uniform thickness up to the edge without having a defect, such as a pinhole, or waviness by a simple method, such as a spin-coating method.

Application of the composition to the entire surface of silicon having a surface layer including an oxide film and a nitride film by a spin-coating method can uniformly form a thin film covering the surface layer. The thin film thus obtained exhibits an effect of improving the wet etching process precision. Specifically, application of an etching solution that selectively etches one of the oxide film or nitride film can significantly reduce the etching rate of the film not to be etched without reducing the etching rate of the film to be etched among the oxide film and the nitride film.

Thus, using the composition in a method of manufacturing a semiconductor element, the method including subjecting the entire surface of silicon having a surface layer including an oxide film and a nitride film to a wet etching process, can form a semiconductor element with a high-precision wiring pattern.

### DESCRIPTION OF EMBODIMENTS

### Composition

A composition according to an embodiment of the present disclosure contains:
a solvent (I) with an SP value of 9.8 (cal/cm³)^{1/2} or more at 25° C., the value being calculated by Fedors' method; and
a cellulose derivative or a salt thereof (II).

The composition can be prepared by mixing and stirring:
a solvent (I) with an SP value of 9.8 (cal/cm³)^{1/2} or more at 25° C., the value calculated by Fedors' method;
a cellulose derivative or a salt thereof (II); and
an additional component as necessary.

### Solvent

The composition contains a solvent (I) with an SP value of 9.8 (cal/cm³)^{1/2} or more at 25° C., the value calculated by Fedors' method, (i.e., a solvent with a high SP value). The solvent (I) has a function of dissolving the cellulose derivative (II).

The SP value of the solvent (I) is more preferably from 9.8 to 14.0 (cal/cm³)^{1/2}, particularly preferably from 10.0 to 12.0 (cal/cm³)^{1/2}, most preferably from 10.0 to 11.4 (cal/cm³)^{1/2}, and especially preferably from 10.0 to 10.5 (cal/cm³)^{1/2}.

The solvent (I) is preferably a solvent with a high SP value as described above and with a high boiling point in terms of being able to reduce the drying rate to prevent coating non-uniformity and/or variation of film thickness due to rapid drying. The boiling point under normal pressure is preferably 100° C. or higher, more preferably 110° C. or higher, even more preferably 120° C. or higher, particularly preferably 130° C. or higher, most preferably 145° C. or higher, and especially preferably 150° C. or higher. From the viewpoint of excellent drying properties of the coating film, the upper limit of the boiling point is preferably 180° C., more preferably 175° C., particularly preferably 170° C., and most preferably 165° C.

The surface tension of the solvent (I) at 25° C. is, for example, preferably 40 dynes/cm or less (e.g., from 15 to 40 dynes/cm) in terms of excellent solubility for the cellulose derivative (II).

Examples of the solvent (I) include a solvent represented by Formula (1) below:

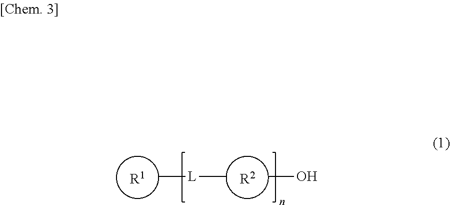

where L represents a single bond, an ether bond, or an ester bond, R¹ represents an alkyl group or a phenyl group, R² represents an alkylene group, R¹ and R² may be bonded to each other to form a ring together with L, a total number of carbon atoms of R¹ and R² is from 3 to 10, and n represents an integer of 1 or more.

Examples of the alkyl group include an alkyl group (linear or branched alkyl group) having from 1 to 9 carbon atoms, such as a methyl group, an ethyl group, a propyl group, an isopropyl group, a butyl group, an isobutyl group, an s-butyl group, a t-butyl group, a pentyl group, a heptyl group, a 2-ethylhexyl group, and an octyl group. Among these, an alkyl group (linear or branched alkyl group) having from 1 to 5 carbon atoms is preferred.

Examples of the alkylene group include an alkylene group having from 1 to 9 carbon atoms, such as a methylene group and an ethylene group. Among these, an alkylene group having from 1 to 5 carbon atoms is preferred, and an alkylene group having from 1 to 3 carbon atoms is particularly preferred.

Examples of the ring that may be formed by R¹ and R² bonded to each other and together with L include an oxirane ring, an oxetane ring, a tetrahydrofuran ring, a propiolactone ring, a butyrolactone ring, and a 8-valerolactone ring.

The total number of carbon atoms of R¹ and R² is from 3 to 10 and particularly preferably from 3 to 6.

In addition, n represents an integer of 1 or more (e.g., an integer of 1 to 5) and is particularly preferably 1 in terms of low viscosity and excellent coating properties.

Examples of the solvent represented by Formula (1) above include methanol, ethanol, n-propyl alcohol, methyl lactate (ML), ethyl lactate (EL), 3-methoxybutanol (MB), tetrahydrofurfuryl alcohol, ethylene glycol monomethyl ether, propylene glycol phenyl ether, diethylene glycol monoethyl ether, ethylene glycol monobutyl ether, diethylene glycol monobutyl ether, propylene glycol monomethyl ether (PGME), and propylene glycol n-propyl ether. One of these can be used alone, or two or more can be used in combination.

The solvent represented by Formula (1) above is preferably at least one selected from propylene glycol monomethyl ether, ethyl lactate, and 3-methoxy butanol.

For the solvent (I), a solvent (I-1) and a solvent (I-2) below may be used in combination. In this case, the solvent (I-1)/the solvent (I-2) (weight ratio) is, for example, from 95/5 to 60/40, preferably from 90/10 to 65/35, and particularly preferably from 85/15 to 70/30.

Solvent (I-1): a solvent with the SP value [(cal/cm³)^{1/2}] of 9.8 to 10.5 (preferably from 10.0 to 10.5) and a boiling point of 100° C. or higher and lower than 130° C.

Solvent (I-2): a solvent with the SP value [(cal/cm³)^{1/2}] of more than 10.5 and a boiling point of 130° C. or higher (preferably 145° C. or higher and most preferably 150° C. or higher). The upper limit of the SP value is, for example, 14.0, and the upper limit of the boiling point is, for example, 180° C.

The solvent (I-1) preferably contains at least propylene glycol monomethyl ether (SP value 10.19, boiling point 121° C.).

The solvent (I-2) preferably contains at least one selected from ethyl lactate (SP value 11.03, boiling point 155° C.) and 3-methoxybutanol (SP value 10.92, boiling point 161° C.).

The solvent (I) preferably contains at least one selected from propylene glycol monomethyl ether, ethyl lactate, and 3-methoxybutanol, particularly preferably contains at least propylene glycol monomethyl ether, and especially preferably contains ethyl lactate and/or 3-methoxybutanol together with propylene glycol monomethyl ether.

The solvent (I) contains propylene glycol monomethyl ether, and ethyl lactate and/or 3-methoxy butanol, and [propylene glycol monomethyl ether]/[ethyl lactate and 3-methoxybutanol] (content weight ratio) is preferably in a range, for example, of 95/5 to 60/40 (preferably of 90/10 to 65/35, particularly preferably of 85/15 to 70/30, and most preferably of 80/20 to 70/30).

The composition may contain an additional solvent in addition to the solvent (I), but the proportion of the solvent (I) in the total amount (100 wt. %) of a volatile component is, for example, 50 wt. % or more, preferably 60 wt. % or more, even more preferably 70 wt. % or more, still more preferably 80 wt. % or more, particularly preferably 95 wt. % or more, and most preferably 99 wt. % or more.

In the present disclosure, “a volatile component” is a component including the solvent (I) and is, for example, a component that volatilizes when the composition is heated at 100° C. for 1 hour under normal pressure.

In addition, the composition may contain water, but in terms of low viscosity and excellent coating properties, the content of water is preferably 10 wt. % or less, more preferably 5 wt. % or less, particularly preferably 3 wt. % or less, most preferably 1 wt. % or less, and especially preferably 0.1 wt. % or less of the total amount of the composition. In the composition containing water in an amount exceeding the above ranges, the cellulose derivative (II) and water molecules form hydrogen bonds thereby increasing the viscosity, and this tends to make formation of a uniform coating film by a spin-coating method difficult.

### Cellulose Derivative or Salt Thereof (II)

The cellulose derivative or a salt thereof (II) (which may be referred to as “the cellulose derivative (II)” in the present specification) has a constituent unit represented by Formula (c) below. The cellulose derivative (II) may have an additional constituent unit in addition to the constituent unit represented by Formula (c) below.

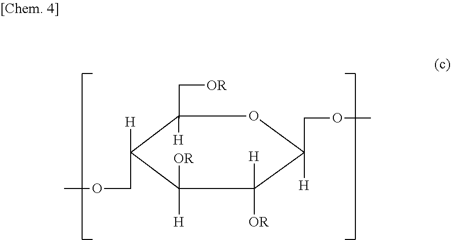

where three Rs are identical or different and represent a hydrogen atom, a hydrocarbon group, or a group in which two or more hydrocarbon groups are bonded through a linking group, and the hydrocarbon group may have a hydroxyl group or a carboxyl group, with proviso that at least one of the three Rs is a hydrocarbon group or a group in which two or more hydrocarbon groups are bonded through a linking group.

The hydrocarbon group is preferably an aliphatic hydrocarbon group and particularly preferably a saturated aliphatic hydrocarbon group (i.e., an alkyl group).

Examples of the alkyl group include an alkyl group having from 1 to 5 carbon atoms, such as a methyl group, an ethyl group, a propyl group, an isopropyl group, a butyl group, an isobutyl group, an s-butyl group, a t-butyl group, and a pentyl group. Among these, the alkyl group is preferably an alkyl group having from 1 to 3 carbon atoms and particularly preferably an alkyl group having 1 or 2 carbon atoms.

The linking group is a divalent group having one or more atoms and preferably an ether bond (—O—).

The group in which two or more hydrocarbon groups are bonded through a linking group is preferably a group represented by Formula (r) below. In Formula (r), the bond extending from the left bonds to an oxygen atom.

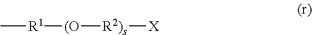

R¹ and R² in Formula (r) above are identical or different and represent a hydrocarbon group. The hydrocarbon group is preferably an aliphatic hydrocarbon group and particularly preferably a saturated aliphatic hydrocarbon group (i.e., an alkylene group). The alkylene group is preferably an alkylene group having from 1 to 3 carbon atoms, such as a methylene group, a dimethylene group, a methylmethylene group, a 1-methylethylene group, a 1,1-dimethylmethylene group, or a trimethylene group, and is particularly preferably an alkylene group having 1 or 2 carbon atoms.

In Formula (r) above, X represents a hydroxyl group or a carboxyl group.

In Formula (r) above, s represents the average number of moles of the added (O—R²) group and is, for example, a number greater than 0, preferably a number greater than 0 and 10 or less, and particularly preferably a number in the range of from 1.5 to 3.

The cellulose derivative having the constituent unit represented by Formula (c) above may form a salt. That is, the hydroxyl group or the carboxyl group of the cellulose derivative may form a salt.

Examples of the salt include a monovalent metal salt, such as an alkali metal salt (such as a lithium salt, a sodium salt, a potassium salt, a rubidium salt, or a cesium salt); a divalent metal salt, such as an alkaline earth metal salt (such as a calcium salt or a magnesium salt): a quaternary ammonium salt, an amine salt, a substituted amine salt, or a double salt of the aforementioned. The salt is preferably an alkali metal salt, such as a sodium salt, or a quaternary ammonium salt.

For example, in the case where the hydroxyl group or the carboxyl group of the cellulose derivative forms a sodium salt, the hydroxyl group (—OH) becomes —ONa, and the carboxyl group (—COOH) becomes —COONa.

The degree of etherification of the cellulose derivative having the constituent unit represented by Formula (c) above can be selected, for example, from a range of 0.1 to 3.0. Above all, from the viewpoint of excellent solubility in the solvent (I), the degree of etherification is preferably 0.5 or more, more preferably 0.8 or more, and particularly preferably 1.0 or more. The upper limit of the degree of etherification is preferably 2.5, more preferably 2.0, and particularly preferably 1.6. The degree of etherification of the cellulose derivative is an average value of the degrees of etherification (or degrees of substitution) of the hydroxyl groups at the 2-, 3-, and 6-positions of the glucose units constituting the cellulose.

The (total) degree of substitution of the cellulose derivative having the constituent unit represented by Formula (c) above (e.g., the (total) degree of substitution of hydrocarbon groups having a hydroxyl group or a carboxyl group) can be selected, for example, from a range of from 0.1 to 3.0. Above all, from the viewpoint of excellent solubility in the solvent (I), the degree of substitution is preferably 0.5 or more, more preferably 0.8 or more, and particularly preferably 1.0 or more. The upper limit of the degree of etherification is preferably 2.5, more preferably 2.0, and particularly preferably 1.6. The (total) degree of substitution of the cellulose derivative is an average value of the degrees of substitution of the hydroxyl groups or the carboxyl groups at the 2-, 3-, and 6-positions of the glucose units constituting the cellulose.

Specific examples of the cellulose derivative (II) include methyl cellulose, ethyl cellulose, hydroxyethyl cellulose, hydroxypropyl cellulose, hydroxypropylmethyl cellulose, carboxymethyl cellulose, and an alkali metal salt of the aforementioned (e.g., sodium carboxymethyl cellulose). One of these can be used alone, or two or more can be used in combination.

The cellulose derivative (II) is preferably at least one selected from ethyl cellulose, hydroxyethyl cellulose, and hydroxypropyl cellulose in terms of excellent solubility in the solvent (I).

The cellulose derivative (II) is preferably hydroxyethyl cellulose in terms of excellent solubility in the solvent (I) and significant improvement in wet etching process precision.

The weight-average molecular weight (Mw) of the cellulose derivative (II) is, for example, from 0.1×10⁴ to 20×10⁴. From the viewpoint of excellent solubility in the solvent (I), the upper limit of the weight-average molecular weight is preferably 15×10⁴, more preferably 10×10⁴, particularly preferably 8×10⁴, most preferably 6×10⁴, and especially preferably 5×10⁴. From the viewpoint of forming a thin film with a moderate strength, the lower limit of the weight-average molecular weight is preferably 0.3×10⁴, more preferably 0.5×10⁴, more preferably 0.8×10⁴, even more preferably 1×10⁴, particularly preferably 2×10⁴, most preferably 3×10⁴, and especially preferably 3.5×10⁴.

The number-average molecular weight (Mn) of the cellulose derivative (II) is, for example, from 0.5×10⁴ to 5×10⁴ and preferably from 0.8×10⁴ to 2.5×10⁴.

The weight-average molecular weight (Mw) and the number-average molecular weight (Mn) are polyethylene oxide equivalent values measured in an aqueous system using gel permeation chromatography (GPC).

In the total amount of the composition, the concentration of the cellulose derivative (II) is, for example, from 0.001 to 3 wt. %. From the viewpoint of forming a thin film with a moderate strength, the lower limit of the concentration is preferably 0.01 wt. %, more preferably 0.05 wt. %, particularly preferably 0.1 wt. %, most preferably 0.25 wt. %, and especially preferably 0.3 wt. %. From the viewpoint of being able to form a uniform coating film, the upper limit of the concentration is preferably 2 wt. %, particularly preferably 1.5 wt. %, most preferably 1.0 wt. %, and especially preferably 0.8 wt. %.

The composition may contain one or two or more polymer compounds in addition to the cellulose derivative (II), but the proportion of the cellulose derivative (II) in the total amount (100 wt. %) of the polymer compounds contained in the composition is, for example, 50 wt. % or more, preferably 60 wt. % or more, more preferably 70 wt. % or more, even more preferably 80 wt. % or more, particularly preferably 95 wt. % or more, and most preferably 99 wt. % or more.

The “polymer compound” in the present specification is a compound with a weight-average molecular weight, for example, of 0.1×10⁴ or more (preferably 0.3×10⁴ or more, more preferably 0.5×10⁴ or more, even more preferably 0.8×10⁴ or more, still more preferably 1×10⁴ or more, particularly preferably 2×10⁴ or more, most preferably 3×10⁴ or more, particularly preferably 3.5×10⁴ or more, and the upper limit is, e.g., 20×10⁴), and examples include poly(vinyl alcohol), poly(vinylpyrrolidone), polyethylene glycol, and polyglycerol.

In addition, in the total amount of a non-volatile component contained in the composition, the proportion of the cellulose derivative (II) is, for example, 30 wt. % or more, preferably 50 wt. % or more, more preferably 60 wt. % or more, even more preferably 70 wt. % or more, still more preferably 80 wt. % or more, particularly preferably 95 wt. % or more, and most preferably 99 wt. % or more.

The composition can contain one or two or more additional components as necessary in addition to the polymer compound. Examples of the additional component include a dispersant and a surfactant. The content of the additional component is, for example, 10 wt. % or less, preferably 5 wt. % or less, and particularly preferably 1 wt. % or less of the total amount of a non-volatile component contained in the composition.

In the present disclosure, “a non-volatile component” is a component including the cellulose derivative (II) and is, for example, a component that remains after the composition is heated at 100° C. for 1 hour under normal pressure.

The composition has excellent coating properties and can form a coating film with a uniform thickness by application by a spin-coating method or the like.

The composition can be used, for example, in an application of forming a thin film used in semiconductor element manufacturing. Examples of the thin film include a resist film used in photolithography, an organic underlayer film, an antireflection film, a thin film used to dope a substrate with an impurity to turn it into a semiconductor, a thin film provided on the surface of silicon to be subjected to wet etching to increase etching selectivity (e.g., an etching selectivity-imparting film), a sealing film, a low-k film, an antistatic film, a diaphragm constituting a semiconductor element, a photosensitive layer, and a light-emitting layer.

### Method of Manufacturing Semiconductor Element

A method of manufacturing a semiconductor element according to an embodiment of the present disclosure includes (1) and (2) below:
(1) applying the composition for forming a thin film described above on a surface layer of silicon, the surface layer including an oxide film and a nitride film, to form a thin film containing the cellulose derivative (II) to obtain a [thin film/surface 5 layer/silicon] laminate; and
(2) bringing an acidic etching liquid selectively etching one of the oxide film or the nitride film into contact with the [thin film/surface layer/silicon] laminate to selectively etch one of the oxide film or the nitride film included in the surface layer. The manufacturing method according to an embodiment of the present disclosure may include an additional process in addition to the above processes and may include, for example, (3) and (4) following (1) and (2):
(3) removing particles by water washing (e.g., water washing using pure 5 water), and
(4) drying

According to the manufacturing method, a thin film containing the cellulose derivative (II) can be uniformly formed. In addition, forming the thin film on a surface layer of silicon, the surface layer including an oxide film and a nitride film, can significantly reduce the etching rate of a film not to be etched without reducing the etching rate of a film to be etched of either the oxide film or the nitride film. Thus, according to the manufacturing method, a film to be etched of either the oxide film or the nitride film can be selectively etched, and a semiconductor element (e.g., a semiconductor chip) with a high-precision wiring pattern can be manufactured with a good yield.

### Process (1)

Process (1) is for applying the composition for forming a thin film described above on a surface layer of silicon (or a silicon wafer), the surface layer including an oxide film and a nitride film, to form a thin film containing the cellulose derivative (II) to obtain a [thin film/surface layer/silicon] laminate (i.e., a laminate having a laminate structure of [thin film/surface layer/silicon]).

The silicon having a surface layer including an oxide film and a nitride film is specifically silicon having a surface layer including a silicon oxide (SiO₂) film and a silicon nitride (Si₃N₄) film.

In the surface layer, the region where the oxide film is present and the region where the nitride film is present may be adjacent to each other or may be separate from each other. The oxide film and the nitride film are preferably exposed to the surface of the surface layer on which the thin film is layered.

The surface layer including an oxide film and a nitride film may be directly layered on silicon or may be layered on an insulating film, a conductive film for forming wiring, and/or the like, layered on the silicon.

The silicon having a surface layer including an oxide film and a nitride film can be manufactured, for example, by subjecting silicon to a film formation process, such as thermal oxidation, chemical vapor deposition (CVD), or physical vapor deposition (PVD).

Examples of the method of applying the composition to a surface layer of silicon, the surface layer including an oxide film and a nitride film, include a method of [1] or [2] below:
[1] a method of immersing silicon having a surface layer including an oxide film and a nitride film in the composition (i.e., a dipping method)
[2] a method of applying the composition onto a surface layer of silicon, the surface layer including an oxide film and a nitride film, (i.e., a coating method)

In the coating method [2], examples of the method of applying the composition onto the surface layer of silicon include a spin-coating method (spin coating), stamping, dispensing, a squeegee method, spraying, and brush coating.

In the manufacturing method according to an embodiment of the present disclosure, the composition for forming a thin film described above is used. Thus, the method can form a thin film with a uniform thickness up to the edge without having a defect, such as a pinhole, or waviness also by a spin-coating method, which is a simple method.

The coating film (the coating film is a coating film containing a solvent) obtained by the dipping method [1] or the coating method [2] may be used as is as the thin film, but a coating film from which the solvent has been removed is preferably used as the thin film in terms of improving the adhesion of the thin film to the surface layer of the silicon and enabling further improvement of the etching selectivity.

It is preferable to form a coating film of the composition on a surface layer of silicon, the surface layer including an oxide film and a nitride film, to subject the resulting coating film to a drying treatment, and to layer a thin film containing a cellulose derivative (II), which has been dried, on the surface layer.

In the case of the dipping method [1], preferably, silicon having a surface layer including an oxide film and a nitride film is immersed in the composition, then pulled up, and then the coating film attached to the surface layer is subjected to drying treatment to form a [thin film/surface layer/silicon] laminate having a thin film from which a solvent has been removed.

In addition, in the case of the coating method [2], preferably, the composition is applied onto a surface layer of silicon, the surface layer including an oxide film and a nitride film, and the resulting coating film is subjected to drying treatment to form a [thin film/surface layer/silicon] laminate having a thin film from which a solvent has been removed.

The “dried thin film containing the cellulose derivative (II)” and the “thin film from which a solvent has been removed” are thin films from which the whole or part of a solvent has been removed, and the content of the solvent is, for example, preferably 30 wt. % or less, particularly preferably 15 wt. % or less, and most preferably 5 wt. % or less of the total amount of the thin film.

Examples of the drying treatment method include a heat-drying method, a ventilation drying method, a reduced-pressure drying method, and a method of blowing a dry gas (e.g., such as nitrogen gas).

In addition, before being subjected to the drying treatment, the thin film may be subjected to water washing treatment. Subjecting the thin film to water washing treatment can remove excess cellulose derivative (II) and can improve the uniformity of the thin film.

That is, a dried thin film containing the cellulose derivative (II) is preferably layered on a surface layer of silicon, the surface layer including an oxide film and a nitride film, by forming a coating film of the composition on the surface layer and subjecting the resulting coating film to water washing treatment and further subjecting the resulting coating film to drying treatment.

In the case of the dipping method [1], preferably, silicon having a surface layer including an oxide film and a nitride film is immersed in the composition for forming a thin film, then pulled up, and then the coating film attached to the surface layer is subjected to water washing treatment and further subjected to drying treatment to form a [thin film/surface layer/silicon] laminate having a thin film from which a solvent has been removed.

In addition, in the case of the coating method [2], preferably, the composition is applied onto a surface layer of silicon, the surface layer including an oxide film and a nitride film, and the resulting coating film is subjected to water washing treatment and further subjected to drying treatment to form a [thin film/surface layer/silicon] laminate having a thin film from which a solvent has been removed.

In the total amount (100 wt. %) of the thin film, the proportion of the weight of the cellulose derivative (II) is, for example, 50 wt. % or more, preferably 60 wt. % or more, more preferably 70 wt. % or more, even more preferably 80 wt. % or more, particularly preferably 95 wt. % or more, and most preferably 99 wt. % or more.

The thin film may further contain an additional component (e.g., such as a polymer compound other than the cellulose derivative (II), a dispersant, and/or a surfactant) in addition to the cellulose derivative (II). The content of the additional component is preferably 5 parts by weight or less, more preferably 3 parts by weight or less, and even more preferably 1 part by weight or less per 100 parts by weight of the cellulose derivative (II).

The thin film obtained by the above method contains the cellulose derivative (II) and has a thickness of, for example, 5 to 200 nm. From the viewpoint of improving the etching selectivity, the thickness of the thin film is preferably from 10 to 150 nm and particularly preferably from 20 to 100 nm.

In addition, according to the above method, a thin film with a uniform thickness up to the edge without having a pinhole or striation is obtained.

### Process (2)

Process (2) is for bringing an acidic etching liquid selectively etching one of the oxide film or the nitride film into contact with the [thin film/surface layer/silicon] laminate obtained through process (1) to selectively etch one of the oxide film or the nitride film included in the surface layer.

The acidic etching liquid is a composition having a function of selectively etching (or dissolving) one of the oxide film or the nitride film and contains at least an acidic substance and a solvent. The acidic etching liquid can be selected and used according to the object to be etched.

In the case of desiring to selectively etch the oxide film, a composition containing as the acidic substance at least one selected from hydrofluoric acid (HF), ammonium fluoride (NH₄F), acidic ammonium fluoride, ammonium hydrogen fluoride, buffered hydrofluoric acid (BHF: a mixture of HF and NH₄F), a mixture of HF and H₂O (DHF), and the like is preferably used as the acidic etching liquid.

In the case of desiring to selectively etch the nitride film, a composition containing hot phosphoric acid as the acidic substance is preferably used as the acidic etching liquid.

The solvent used in the acidic etching liquid is preferably water. In addition, a water-soluble organic solvent (e.g., such as lactone or a polyhydric alcohol) may be used together with water.

The concentration of the acidic substance in the acidic etching liquid is, for example, from 0.05 to 99 wt. %. The concentration of the acidic substance can be appropriately adjusted according to the type of acidic substance.

In the case of using hydrofluoric acid, ammonium fluoride, acidic ammonium fluoride, ammonium hydrogen fluoride, BHF, or DHF as the acidic substance, the concentration of the previous acidic substance in the acidic etching liquid is preferably from 0.05 to 30 wt. %.

In the case of using hot phosphoric acid as the acidic substance, the concentration of the acidic substance in the acidic etching liquid is preferably from 70 to 99 wt. %, particularly preferably from 72 to 90 wt. %, and most preferably from 75 to 85 wt. %.

The method of bringing the acidic etching liquid into contact with the [thin film/surface layer/silicon] laminate is not particularly limited, and examples include methods [3] and [4] below:
[3] a method of immersing the [thin film/surface layer/silicon] laminate in an acidic etching liquid (i.e., a dipping method)
[4] a method of applying an acidic etching liquid onto the thin film of the [thin film/surface layer/silicon] laminate (i.e., a coating method)

In the dipping method [3], the immersion time is, for example, from 0.1 to 5 minutes and preferably from 0.5 to 3 minutes. The immersion temperature (e.g., the temperature of the acidic etching liquid during immersion) is, for example, from 20 to 30° C.

According to the dipping method [3], the amount of the acidic etching liquid to be used can be reduced, which is economical. In addition, the etching process can be speedily performed, thus achieving high productivity.

In the coating method [4], examples of the method of applying the acidic etching liquid onto the thin film of the [thin film/surface layer/silicon] laminate include a spin-coating method (spin coating), stamping, dispensing, a squeegee method, spraying, and brush coating.

According to the coating method [4], contamination of the silicon by the acidic etching liquid can be prevented.

The etching selectivity ratio of one of the oxide film or the nitride film to the other in the method according to an embodiment of the present disclosure is, for example, 10 or more and preferably 15 or more. The etching selectivity ratio is a ratio between the etching rate of the oxide film and the etching rate of the nitride film and is an etching selectivity ratio [oxide film/nitride film] or an etching selectivity ratio [nitride film/oxide film].

The etching selectivity ratio [oxide film/nitride film] is [etching rate of the oxide film]/[etching rate of the nitride film], and the etching selectivity ratio [nitride film/oxide film] is [etching rate of nitride film]/[etching rate of oxide film].

The etching selectivity ratio [oxide film/nitride film] is, for example, 10 or more and more preferably 15 or more.

In the method according to an embodiment of the present disclosure, a decrease in the etching rate of a film to be etched of either the oxide film or the nitride film is suppressed even with the thin film provided, and a high etching rate can be maintained.

The etching rate of the film to be etched is, for example, 85% or more, preferably 90% or more, more preferably 95% or more, particularly preferably 98% or more, and most preferably 99% or more of the etching rate under the same conditions except that the thin film is not provided. That is, the decrease in the etching rate by the thin film is, for example, 15% or less, preferably 10% or less, more preferably 5% or less, particularly preferably 2% or less, and most preferably 1% or less.

In the method according to an embodiment of the present disclosure, providing the thin film can significantly reduce the etching rate of a film not to be etched of either the oxide film or the nitride film.

The etching rate of the film not to be etched is, for example, 50% or less and preferably 30% or less of the etching rate under the same conditions except that the thin film is not provided. That is, the decrease in the etching rate due to the thin film is, for example, 50% or more, preferably 60% or more, and more preferably 70% or more.

In the method according to an embodiment of the present disclosure, the etching rate of a film not to be etched of either the oxide film or the nitride film is, for example, 15 nm/min or less, preferably 10 nm/min or less, and particularly preferably 5 nm/min or less (e.g., from 3 to 5 nm/min).

In the method according to an embodiment of the present disclosure, the etching rate of the oxide film in the case of using an acidic etching liquid that selectively etches the oxide film is, for example, 85% or more, preferably 90% or more, more preferably 95% or more, particularly preferably 98% or more, and most preferably 99% or more of the etching rate of the oxide film under the same conditions except that the thin film is not provided. That is, the decrease in the etching rate by the thin film is, for example, 15% or less, preferably 10% or less, more preferably 5% or less, particularly preferably 2% or less, and most preferably 1% or less.

In the method according to an embodiment of the present disclosure, the etching rate of the nitride film in the case of using an acidic etching liquid that selectively etches the oxide film is, for example, 15 nm/min or less, preferably 10 nm/min or less, and particularly preferably 5 nm/min or less (e.g., from 3 to 5 nm/min).

A semiconductor element obtained through the above processes is then subjected to lithography, dry etching, film formation, CMP, washing, wire bonding, molding, and/or the like, and a semiconductor device can be manufactured, accordingly.

Examples of the semiconductor device include an integrated circuit, such as an IC and an LSI: a light-emitting device, such as an LED: a light-receiving device, such as a solar cell, an optical sensor, and a CMOS image sensor; a semiconductor sensor, such as an MEMS: a memory, an analog IC, and a transistor.

The configurations and combinations thereof of the present disclosure described above are merely examples, and addition, omission, substitution, and modification of the configurations can be appropriately made without departing from the gist of the present disclosure. In addition, the present disclosure is not limited by the embodiments and is limited only by the claims.

### EXAMPLES

The present disclosure will next be described in more detail by way of Examples, but the present disclosure is not limited to the Examples.

Solvents, polymer compounds, and silicon used in examples and comparative examples are as follows.

### Solvents

PGME: propylene glycol monomethyl ether, SP value: 10.19, boiling point: 121° C., surface tension at 25° C.: 28 dynes/cm
EL: ethyl lactate, SP value: 11.03, boiling point: 155° C., surface tension at 25° C.: 28.7 dynes/cm
MB: 3-methoxy butanol, SP value: 10.92, boiling point: 161° C., surface tension at 25° C.: 29.7 dynes/cm

### Polymer Compounds

HEC: hydroxyethyl cellulose (degree of etherification of 1.2 to 1.4, Mw 4.0×10⁴, Mn: 12000, surface tension at 25° C.: 45 to 46 dynes/cm)
HPC: hydroxypropyl cellulose (Mw: 3.4×10⁴, Mn: 11000, surface tension at 25° C.: 45 to 46 dynes/cm, available from Aldrich)
EC: ethyl cellulose (weight-average molecular weight 1.8×10⁵, surface tension at 25° C.: 45 to 46 dynes/cm, available from Hayashi Pure Chemical Ind., Ltd.)

### Silicon Having Oxide Film or Nitride Film

Silicon substrate with a Si₃N₄ film: a silicon substrate with a 300-nm-thick Si₃N₄ film formed by plasma-CVD, trade name “PE-SiN”, available from Advantec Co., Ltd.
Silicon substrate with a SiO₂ film: a silicon substrate with a 1.5-μm-thick SiO₂ film formed by thermal oxidation, trade name “Th-SiO₂”, available from Advantec Co., Ltd.

### Example 1A

### Preparation of Composition for Forming Thin Film

PGME was used as the solvent (I) and HEC was used as the cellulose derivative (II). One (1) gram of PGME and 0.003 g of HEC were mixed and stirred overnight in a ball-mill, and a composition 1 for forming a thin film was obtained.

### Thin Film Preparation

The silicon substrate with a Si₃N₄ film was spin-coated with the composition 1 for forming a thin film using a spin coater (available from MIKASA CO., LTD.), then heated on a hot plate at 150° C. for 120 seconds, and a laminate having a thin film 1 on the substrate surface ([thin film 1/Si₃N₄/silicon substrate] laminate).

The resulting thin film I was uniform without a defect, such as a pinhole; color unevenness: or peripheral waviness.

The thickness of the thin film I was 12 nm as measured with a spectroscopic ellipsometer (trade name “FE-5000”, available from Otsuka Electronics Co., Ltd.).

### Example 2A

A composition for forming a thin film was obtained and a laminate having a thin film was obtained in the same manner as in Example IA except that a mixture of PEGM and EL (PEGM/EL (weight ratio)=7/3) was used as the solvent (I).

### Example 3A

A composition for forming a thin film was obtained and a laminate having a thin film was obtained in the same manner as in Example IA except that a mixture of PEGM and EL (PEGM/EL (weight ratio)=8/2) was used as the solvent (I).

### Example 4A

A composition for forming a thin film was obtained and a laminate having a thin film was obtained in the same manner as in Example IA except that a mixture of PEGM and MB (PEGM/MB (weight ratio)=7/3) was used as the solvent (I).

### Example 5A

A laminate having a thin film was obtained in the same manner as in Example 2A except that the thickness of the thin film was changed to 22 nm.

### Example 6A

A composition for forming a thin film was obtained and a laminate having a thin film was obtained in the same manner as in Example IA except that HPC was used instead of HEC as the cellulose derivative (II).

### Example 7A

A composition for forming a thin film was obtained and a laminate having a thin film was obtained in the same manner as in Example 1A except that EC was used instead of HEC as the cellulose derivative (II).

### Comparative Example 1A

A composition for forming a thin film was obtained and a laminate having a thin film was obtained in the same manner as in Example 1A except that water was used instead of PGME as the solvent (I).

### Evaluation 1

For the thin films obtained in Examples 1A to 7A and Comparative Example 1A, the appearance was visually observed to determine the presence or absence of a pinhole, the presence or absence of color unevenness, and the presence or absence of peripheral waviness. The results are summarized and shown in Table 1 below.

TABLE 1

| | | Example | Example | Example | Example | Example | Example | Example | Comparative |
|---|---|---|---|---|---|---|---|---|---|
| | | 1A | 2A | 3A | 4A | 5A | 6A | 7A | Example 1A |
| Composition for | Solvent | PGME | PGME/EL | PGME/EL | PGME/MB | PGME/EL | PGME | PGME | Water |
| forming thin film | weight ratio | | 7/3 | 8/2 | 7/3 | 7/3 | | | |
| | Polymer compound | HEC | HEC | HEC | HEC | HEC | HPC | EC | HEC |
| Thin film | Average thickness | 12 | 12 | 12 | 12 | 22 | 12 | 12 | 12 |
| | (nm) | | | | | | | | |
| | Pinhole | None | None | None | None | None | None | None | Present |
| | Color unevenness | None | None | None | None | None | None | None | Present |
| | Peripheral waviness | None | None | None | None | None | None | None | Large |
| | | | | | | | | | waviness |
| | | | | | | | | | was present |

### Evaluation 2

For the laminates having a thin film obtained in Examples 1A to 7A and Comparative Example 1A, an etching process 1 was performed by the following method, and the etching rate was calculated. In addition, the substrate surface after etching was observed with an optical microscope to determine the presence or absence of a pinhole and the like.

### Etching Process 1

The [thin film/Si₃N₄ film/silicon substrate] laminate was immersed in a buffered hydrofluoric acid (trade name “BHF110”, available from Daikin Industries, Ltd.) and allowed to stand for 5 minutes, and, an etched laminate was obtained, accordingly.

### Etching Rate Calculation

For the laminate after the etching process, the film thickness was measured with a spectroscopic ellipsometer (trade name “FE-5000”, available from Otsuka Electronics Co., Ltd.) to calculate the etching rate.

### Examples 1B to 7B and Comparative Example 1B

Compositions for forming a thin film were obtained and laminates having a thin film ([thin film/SiO₂ film/silicon substrate] laminates) were obtained each in the same manner as in Examples 1A to 7A and Comparative Example 1A except that a silicon substrate with a SiO₂ film was used instead of the silicon substrate with a Si₃N₄ film.

### Evaluation 3

For the laminates having a thin film obtained in Examples 1B to 7B and Comparative Example 1B, an etching process 2 was performed by the following method, and the etching rate was calculated.

### Etching Process 2

The [thin film/SiO₂ film/silicon substrate] laminate was immersed in a buffered hydrofluoric acid (trade name “BHF110”, available from Daikin Industries, Ltd.) and allowed to stand for 5 minutes, and, an etched laminate was obtained, accordingly.

### Etching Rate Calculation

Regarding the laminate after the etching process, the film thickness was measured with a spectroscopic ellipsometer (trade name “FE-5000”, available from Otsuka Electronics Co., Ltd.) to calculate the etching rate.

### Comparative Example 2

The etching process 1 and the etching process 2 were performed in the same manner as in Examples 1A and 1B except that the thin film was not formed, and the etching rate was calculated.

Regarding Examples 1A to 7A, Comparative Example 1A, Examples 1B to 7B, Comparative Example 1B, and Comparative Example 2, the evaluation results are summarized and shown in Table 2 below.

TABLE 2

| | | Example | Example | Example | Example | Example | Example | Example | Comparative | Comparative |
|---|---|---|---|---|---|---|---|---|---|---|
| | | 1 | 2 | 3 | 4 | 5 | 6 | 7 | Example 1 | Example 2 |
| Composition | Solvent | PGME | PGME/EL | PGME/EL | PGME/MB | PGME/EL | PGME | PGME | Water | — |
| for forming | weight ratio | | 7/3 | 8/2 | 7/3 | 7/3 | | | | |
| thin film | Polymer | HEC | HEC | HEC | HEC | HEC | HPC | EC | HEC | — |
| | compound | | | | | | | | | |
| Film thickness | | 12 | 12 | 12 | 12 | 20 | 12 | 12 | 12 | — |
| Etching rate | Th-SiO₂ | 60.5 | 60.4 | 60.5 | 60.6 | 60.4 | 60.3 | 60.3 | 60.5 | 60.6 |
| (nm/min) | PE-SIN | 4.5 | 4 | 4.1 | 4.2 | 3.6 | 15.2 | 15.5 | 4.6 | 19.8 |

| | | | | | | | | | |
|---|---|---|---|---|---|---|---|---|---|
| [SiO₂/Si₃N₄] selectivity | 13.4 | 15.1 | 14.8 | 14.4 | 16.8 | 4.0 | 3.9 | 13.2 | 3.1 |
| ratio | | | | | | | | | |
| Color unevenness | None | None | None | None | None | None | None | Present | Present |

Table 2 shows that, in the etching process with the acidic etching liquid that selectively etches the oxide film, the thin film containing the cellulose derivative (II) significantly suppresses etching of the nitride film while maintaining etching of the oxide film, and thereby improves the etching selectivity.

To summarize the above, configurations and variations of the present disclosure are additionally described below.

[1] A composition for forming a thin film, the composition containing:
a solvent (I) with an SP value of 9.8 (cal/cm³)^{1/2} or more at 25° C., the value calculated by Fedors' method; and
a cellulose derivative having a constituent unit represented by Formula (c) or a salt thereof (II).

[2] The composition according to [1], in which the solvent (I) is a solvent (I) with an SP value of 9.8 (cal/cm³)^{1/2} or more at 25° C., the value calculated by Fedors' method, and a surface tension of 40 dynes/cm or less at 25° C.

[3] The composition according to [1] or [2], in which the solvent (I) contains a solvent (I-1) and a solvent (I-2) below, and the solvent (I-1)/the solvent (I-2) (weight ratio) is from 95/5 to 60/40:
the solvent (I-1): a solvent (I) with an SP value of 9.8 to 10.5 (cal/cm³)^{1/2} at 25° C., the value calculated by Fedors' method, and a boiling point of 100° C. or higher and less than 130° C.; and
the solvent (I-2): a solvent with an SP value of more than 10.5 (cal/cm³)^{1/2} at 25° C., the value calculated by Fedors' method, and a boiling point of 130° C. or higher.

[4] The composition for forming a thin film according to [1], in which the solvent (I) is a solvent represented by Formula (1):

[5] The composition according to [1], in which the solvent (I) contains at least one selected from propylene glycol monomethyl ether, ethyl lactate, and 3-methoxy butanol.

[6] The composition according to [1], in which the solvent (I) contains propylene glycol monomethyl ether.

[7] The composition according to [1], in which the solvent (I) contains propylene glycol monomethyl ether, and ethyl lactate and/or 3-methoxy butanol, and [content weight of propylene glycol monomethyl ether]/[total content weight of ethyl lactate and 3-methoxy butanol] is from 95/5 to 60/40.

[8] The composition according to any one of [1] to [7], in which a content of water is 10 wt. % or less of a total amount of the composition.

[9] The composition according to any one of [1] to [8], in which a content of the cellulose derivative or a salt thereof (II) is 30 wt. % or more of a total amount of a non-volatile component contained in the composition.

[10] The composition according to any one of [1] to [9], in which a proportion of the cellulose derivative or a salt thereof (II) is 70 wt. % or more in a total amount of polymer compounds with a weight-average molecular weight of 0.1×10⁴ or more contained in the composition.

[11] The composition according to any one of [1] to [10], in which the cellulose derivative is at least one selected from ethyl cellulose, hydroxyethyl cellulose, and hydroxypropyl cellulose.

[12] The composition according to any one of [1] to [10], in which the cellulose derivative contains at least hydroxyethyl cellulose.

[13] The composition according to any one of [1] to [12], in which the cellulose derivative or a salt thereof (II) has a weight-average molecular weight of 0.1×10⁴ to 20×10⁴.

[14] The composition according to any one of [1] to [13], in which a concentration of the cellulose derivative or a salt thereof (II) is from 0.001 to 3 wt. % in the total amount of the composition.

[15] Use of the composition described in any one of [1] to [14], as a composition for forming a thin film.

[16] A method of manufacturing a semiconductor element using the composition described in any one of [1] to [14].

[17] A method of manufacturing a semiconductor element, the method obtaining a semiconductor element through (1) and (2) below:
(1) applying the composition described in any one of [1] to [14] to a surface layer of silicon, the surface layer including an oxide film and a nitride film, to form a thin film containing the cellulose derivative or a salt thereof (II) to obtain a [thin film/surface layer/silicon] laminate; and
(2) bringing an acidic etching liquid selectively etching one of the oxide film or the nitride film into contact with the [thin film/surface layer/silicon] laminate to selectively etch one of the oxide film or the nitride film included in the surface layer.

[18] The method of manufacturing a semiconductor element according to [17], in which the acidic etching liquid is at least one selected from hydrofluoric acid, ammonium fluoride, and a mixture of these.

### INDUSTRIAL APPLICABILITY

The composition of the present disclosure has excellent coating properties and can form a thin film with a uniform thickness up to the edge without having a defect, such as a pinhole or waviness by a simple method, such as a spin-coating method.

In addition, forming the thin film using the composition on a surface layer of silicon having the surface layer, the surface layer including an oxide film and a nitride film, can significantly improve the etching selectivity of the wet etching process and can form a semiconductor element with a high-precision wiring pattern.

1. A composition for forming a thin film, the composition comprising:
a solvent (I) with an SP value of 9.8 (cal/cm³)^{1/2} or more at 25° C., the value calculated by Fedors' method; and
a cellulose derivative comprising a constituent unit represented by Formula (c) or a salt thereof (II): 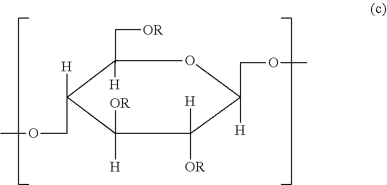
where three Rs are identical or different and represent a hydrogen atom, a hydrocarbon group, or a group in which two or more hydrocarbon groups are bonded through a linking group, and the hydrocarbon group may have a hydroxyl group or a carboxyl group, with proviso that at least one of the three Rs is a hydrocarbon group or a group in which two or more hydrocarbon groups are bonded through a linking group.

2. The composition for forming a thin film according to claim 1, wherein the solvent (I) is a solvent represented by Formula (1): 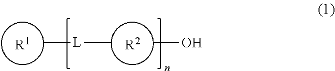
where L represents a single bond, an ether bond, or an ester bond, R¹ represents an alkyl group or a phenyl group, R² represents an alkylene group, R¹ and R² may be bonded to each other to form a ring together with L, a total number of carbon atoms of R¹ and R² is from 3 to 10, and n represents an integer of 1 or more.

3. The composition for forming a thin film according to claim 1, wherein the solvent (I) comprises propylene glycol monomethyl ether.

4. The composition for forming a thin film according to claim 1, wherein a content of water is 10 wt. % or less of a total amount of the composition.

5. The composition for forming a thin film according to claim 1, wherein a content of the cellulose derivative or the salt thereof (II) is 30 wt. % or more of a total amount of a non-volatile component contained in the composition.

6. A method of manufacturing a semiconductor element using the composition for forming a thin film described in claim 1.

7. A method of manufacturing a semiconductor element, the method obtaining a semiconductor element through (1) and (2) below:
(1) applying the composition for forming a thin film described in claim 1 to a surface layer of silicon, the surface layer comprising an oxide film and a nitride film, to form a thin film comprising the cellulose derivative or the salt thereof (II) to obtain a thin film/surface layer/silicon laminate; and
(2) bringing an acidic etching liquid selectively etching one of the oxide film or the nitride film into contact with the thin film/surface layer/silicon laminate to selectively etch one of the oxide film or the nitride film included in the surface layer.

8. The method of manufacturing a semiconductor element according to claim 7, wherein the acidic etching liquid is at least one selected from hydrofluoric acid, ammonium fluoride, and a mixture thereof.

9. The composition for forming a thin film according to claim 1, wherein the solvent (I) is a solvent with an SP value of 9.8 (cal/cm³)^{1/2} or more at 25° C., the value calculated by Fedors' method, and a surface tension of 40 dynes/cm or less at 25° C.

10. The composition for forming a thin film according to claim 1, wherein the solvent (I) comprises a solvent (I-1) and a solvent (I-2):
the solvent (I-1): a solvent with an SP value of from 9.8 to 10.5 (cal/cm³)^{1/2} at 25° C., the value calculated by Fedors' method, and a boiling point of 100° C. or higher and lower than 130° C.
the solvent (I-2): a solvent with an SP value of more than 10.5 (cal/cm³)^{1/2} at 25° C., the value calculated by Fedors' method, and a boiling point of 130° C. or higher.

11. The composition for forming a thin film according to claim 10, wherein the solvent (I-1) comprises at least propylene glycol monomethyl ether, and the solvent (I-2) comprises at least one selected from ethyl lactate and 3-methoxybutanol.

12. The composition for forming a thin film according to claim 1, wherein
the solvent (I) comprises a solvent (I-1) and a solvent (I-2), and
a weight ratio of the solvent (I-1) to the solvent (I-2) is from 95/5 to 60/40:
the solvent (I-1): a solvent with an SP value of from 9.8 to 10.5 (cal/cm³)^{1/2} at 25° C., the value calculated by Fedors' method, and a boiling point of 100° C. or higher and lower than 130° C.
the solvent (I-2): a solvent with an SP value of more than 10.5 (cal/cm³)^{1/2} at 25° C., the value calculated by Fedors' method, and a boiling point of 130° C. or higher.

13. The composition for forming a thin film according to claim 1, wherein the solvent (I) comprises propylene glycol monomethyl ether (I-1′), and ethyl lactate and/or 3-methoxybutanol (I-2′), and
a weight ratio of the (I-1′) to the (I-2′) is from 95/5 to 60/40.

14. The composition for forming a thin film according to claim 1, wherein the cellulose derivative is at least one selected from ethyl cellulose, hydroxyethyl cellulose, and hydroxypropyl cellulose.

15. The composition for forming a thin film according to claim 1, wherein the cellulose derivative comprises at least hydroxyethyl cellulose.

16. The composition for forming a thin film according to claim 1, wherein a degree of etherification of the cellulose derivative is in a range of from 0.8 to 1.6.

17. The composition for forming a thin film according to claim 1, wherein the cellulose derivative comprises at least hydroxyethyl cellulose with a weight-average molecular weight of from 0.1×10⁴ to 20×10⁴.

18. The composition for forming a thin film according to claim 1, wherein a weight-average molecular weight of the cellulose derivative or the salt thereof (II) is from 0.1×10⁴ to 20×10⁴.

19. The composition for forming a thin film according to claim 1, wherein a concentration of the cellulose derivative or the salt thereof (II) is from 0.001 to 3 wt. % based on a total amount of the composition.

20. The composition for forming a thin film according to claim 1, wherein a proportion of the cellulose derivative or the salt thereof (II) is 95 wt. % or more based on a total amount of polymer compounds with a weight-average molecular weight of 0.1×10⁴ or more contained in the composition.
